(19) United States
(12) Patent Application Publication
(10) Pub. No.: US 2010/0316080 A1
(43) Pub. Date: Dec. 16, 2010

(54) SEMICONDUCTOR OPTICAL ELEMENT

(75) Inventors: Harunaka Yamaguchi, Tokyo (JP); Chikara Watatani, Tokyo (JP); Masayoshi Takemi, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/700,769

(22) Filed: Feb. 5, 2010

(30) Foreign Application Priority Data
Jun. 15, 2009 (JP) 2009-141782

(51) Int. Cl. H01S 5/323

(52) U.S. Cl. 372/46.01

(57) ABSTRACT

A semiconductor optical element includes a p-type InP substrate doped with Zn; and a diffusion blocking layer doped with Ru, a p-type InP cladding layer, an active layer, and an n-type InP cladding layer sequentially arranged on the p-type InP substrate.

### BACKGROUND OF THE INVENTION

1. Field of the Invention

The present invention relates to a semiconductor optical element including a p-type InP substrate doped with Zn, and more particularly to a semiconductor optical element capable of preventing Zn diffusion from the substrate.

2. Background Art

Zn is mainly used as a p-type impurity for InP. However, Zn is likely to diffuse in a crystal such as InP. It is necessary to use a p-type impurity other than Zn or prevent Zn diffusion so as to prevent p-type impurity diffusion.

Be, Mg or the like are known as a p-type impurity used for InP which is less likely to diffuse than Zn. However, a doping crystal growth of Be, Mg or the like is difficult, and it is difficult to use Be, Mg or the like as a p-type impurity for all the layers of the semiconductor optical element from the standpoint of the device yield and the dopant material stable supply.

As a method for preventing Zn diffusion, ruthenium (Ru) doping in InP has been recently attracting attention. InP doped with Ru is semi-insulating, as InP doped with Fe. Mutual diffusion rarely occurs between Zn and Ru. For example, there has been proposed a technique that a Ru-doped layer is inserted between a Fe-doped semi-insulating substrate and a Zn-doped layer so as to prevent mutual diffusion between Fe and Zn (for example, see Japanese Laid-Open Patent Publication No. 2002-344087).

### SUMMARY OF THE INVENTION

When a semiconductor optical element is manufactured, a p-type InP buffer layer, a p-type InP clad layer, an active layer, and a n-type InP clad layer are sequentially formed on a p-type InP substrate. If the semiconductor optical element has a buried structure, a mesa is formed on both sides of the active layer and the mese is buried. Next, a contact layer for connecting to an electrode is grown. Therefore, plurality of crystal growths are performed.

The Zn concentration (2 to 4×10¹⁸ cm³) of the p-type InP substrate is higher than the Zn concentration (1×10¹⁸ cm⁻³) of the p-type InP clad layer. Therefore, by a heat treatment, Zn of the p-type InP substrate is diffused into the p-type InP clad layer, and further into the active layer located on the top of the p-type InP clad layer. Thereby, there is a problem that the emission efficiency of the semiconductor optical element is reduced. Particularly, in the case of the semiconductor optical element having the buried structure, many crystal growth is performed and thereby many high-temperature heat treatment is performed. As a result, this problem becomes more serious in the case.

The present invention has been implemented to solve the above described problem and it is an object of the present invention to provide a semiconductor optical element capable of preventing Zn diffusion from a p-type InP substrate doped with Zn.

According to one aspect of the present invention, a semiconductor optical element comprises: a p-type InP substrate doped with Zn; and a diffusion blocking layer doped with Ru, a p-type InP clad layer, an active layer, and an n-type InP clad layer which are sequentially formed on the p-type InP substrate.

The present invention can prevent Zn diffusion from a substrate.

Other and further objects, features and advantages of the invention will appear more fully from the following description.

### BRIEF DESCRIPTION OF THE DRAWINGS

FIG. 1 is a sectional view of a semiconductor optical element according to an embodiment of the present invention.

FIGS. 2 to 8 are sectional views for illustrating a method for manufacturing a semiconductor optical element according to an embodiment of the present invention.

### DETAILED DESCRIPTION OF THE PREFERRED EMBODIMENTS

Now, embodiments of the present invention will be described with reference to the drawings. Like reference numerals denote like components throughout the drawings, and redundant descriptions will be omitted.

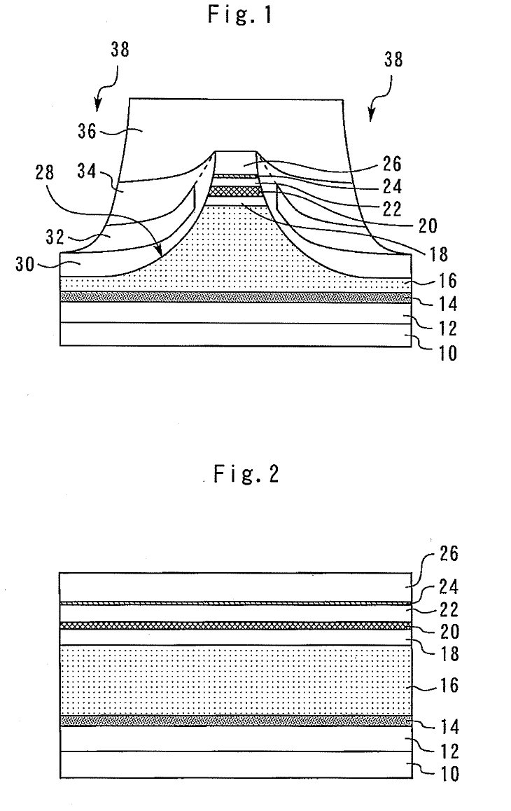

FIG. 1 is a sectional view of a semiconductor optical element according to an embodiment of the present invention. A p-type InP substrate 10 is doped with Zn as an p-type impurity.

A p-type InP buffer layer 12 doped with Zn, an InP diffusion blocking layer 14 doped with Ru, a p-type InP clad layer 16, a p-type InGaAsP optical confinement layer 18, an active layer 20 made of InGaAsP, an n-type InGaAsP optical confinement layer 22, an n-type InGaAsP guiding layer 24, and an n-type InP clad layer 26 are sequentially formed on the p-type InP substrate 10. The active layer 20 has a multiple quantam well (MQW) structure including InGaAsP quantum well layers and InGaAsP barrier layers. In these layers, S or Si is used as an n-type impurity.

The p-type InP clad layer 16 is doped with Be. Other p-type impurity whose diffusion coefficient is lower than Zn, for example Mg, can be used instead of Be. The Zn concentration of the p-type InP buffer layer 12 is lower than that of the p-type InP substrate 10.

The p-type InP clad layer 16, the p-type InGaAsP optical confinement layer 18, the InGaAsP active layer 20, the n-type InGaAsP optical confinement layer 22, the n-type InGaAsP guiding layer 24, and the n-type InP clad layer 26 are etched so as to form a mesa stripe 28 extended in an optical-waveguide direction. The width of the mesa stripe 28 is widened toward the p-type InP substrate 10.

A p-type InP burying layer 30, a n-type InP current blocking layer 32, and a p-type InP current blocking layer 34 are buryed on both sides of the mesa stripe 28. An n-type InP contact layer 36 is formed on the n-type InP clad layer 26. Thus, a pnp-type current blocking structure is buryed on both sides of the mesa stripe 28. Thereby, a driving current efficiently flows through the active layer 20 in the mesa stripe 28.

The n-type InP contact layer 36, the p-type InP burying layer 30, the n-type InP current blocking layer 32, and the p-type InP current blocking layer 34 are etched so as to form an isolation groove 38. The InP diffusion blocking layer 14 exists under the bottoms of the mesa stripe 28 and the isolation groove 38.

When the power is applied to this semiconductor optical element, a positive electric field is applied to the p-type InP substrate 10 side and a negative electric field is applied to the n-type InP contact layer 36 side. Holes are injected from the p-type InP clad layer 16 into the active layer 20 and electrons are injected from the n-type InP clad layer 26 into the active layer 20. As a result of the combining of the holes and the electrons, laser light is emitted from the active layer 20.

A method for manufacturing the semiconductor optical element will be described.

First, as shown in FIG. 2, the p-type InP substrate 10 doped with Zn is prepared. The p-type InP buffer layer 12 doped with Zn, the InP diffusion blocking layer 14 doped with Ru, the p-type InP clad layer 16, the p-type InGaAsP optical confinement layer 18, the active layer 20, the n-type InGaAsP optical confinement layer 22, the n-type InGaAsP guiding layer 24, and the n-type InP clad layer 26 are sequentially formed on the p-type InP substrate 10 by metal organic vapor phase epitaxy (MOVPE).

When these layers are formed, a growing temperature is 650° C. and a growing pressure is 100 mbar for example. As raw material gases to form these layers, trimethylindium (TMI), trimethylgallium (TMG), phosphine (PH₃: Phosphine), arsine (AsH₃), diethylzinc (DEZ), and H₂S (H₂ S) are used. By controlling these raw material gases by a mass flow controller (MFC), desired compositions of these layers can be obtained.

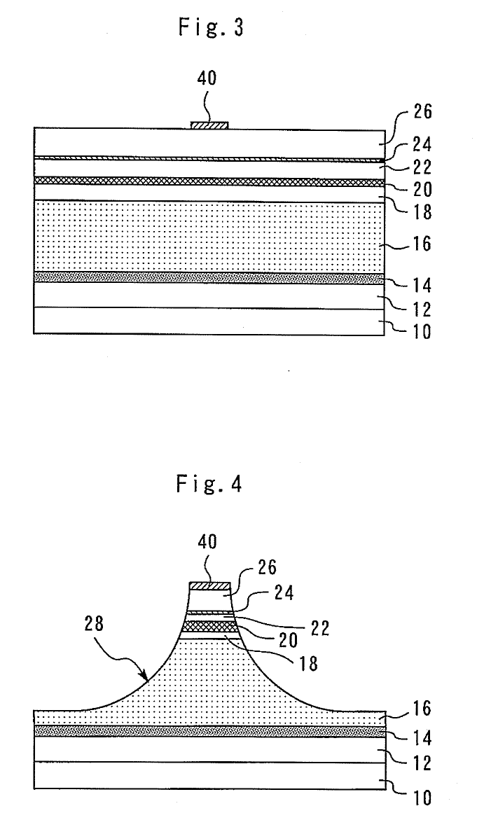

Next, as shown in FIG. 3, a SiO₂ film 40 is formed on the n-type InP clad layer 26. The SiO₂ film 40 is patterned by photolithography so that the SiO₂ film 40 remains only on the top of the mesa stripe 28.

Next, as shown in FIG. 4, the p-type InP clad layer 16, the p-type InGaAsP optical confinement layer 18, the InGaAsP active layer 20, the n-type InGaAsP optical confinement layer 22, the n-type InGaAsP guiding layer 24, and the n-type InP clad layer 26 are wet-etched by wet etchant such as HBr and using the SiO₂ film 40 as a mask so as to form the mesa stripe 28. At this time, the InP diffusion blocking layer 14 is prevented from etching.

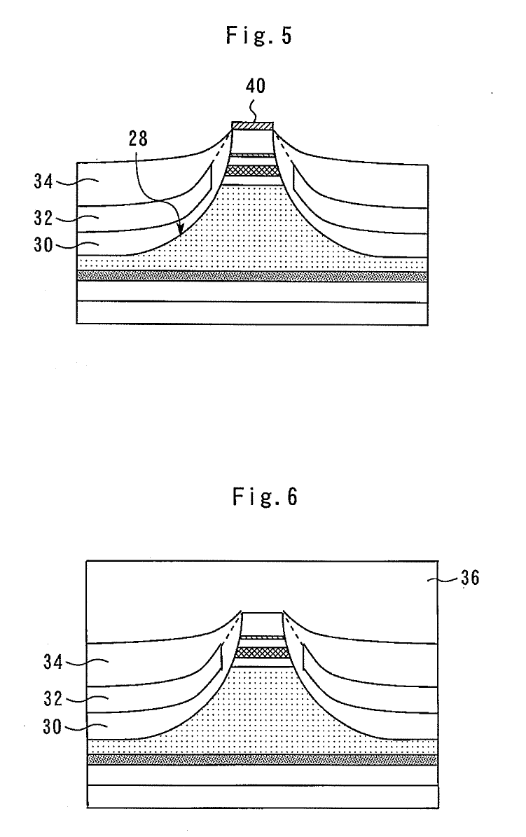

Next, as shown in FIG. 5, the p-type InP burying layer 30, the n-type InP current blocking layer 32, and the p-type InP current blocking layer 34 are sequentially formed on both sides of the mesa stripe 28. Then, the SiO₂ film 40 is removed by wet etchant such as HF.

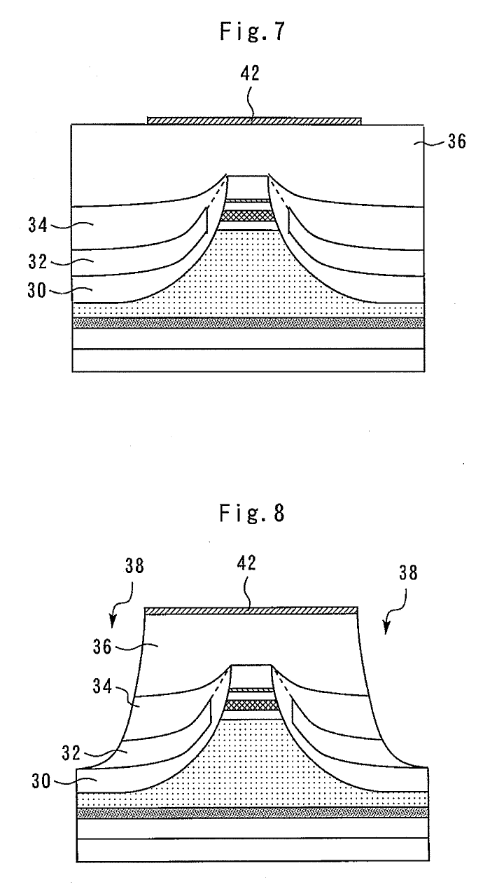

Next, as shown in FIG. 6, the n-type InP contact layer 36 are formed on the n-type InP clad layer 26 and the p-type InP current blocking layer 34. Then, as shown in FIG. 7, a SiO₂ film 42 is formed on the n-type InP contact layer 36. The SiO₂ film 42 is patterned by photolithography.

Next, as shown in FIG. 8, the p-type InP burying layer 30, the n-type InP current blocking layer 32, and the p-type InP current blocking layer 34 are wet-etched by wet etchant such as HBr and using the SiO₂ film 42 as a mask so as to form the isolation groove. At this time, the InP diffusion blocking layer 14 is prevented from etching. The SiO₂ film 42 is removed by wet etchant such as HF.

The semiconductor optical element according to the embodiment of the present invention is formed in the above described processes.

In this embodiment, the InP diffusion blocking layer 14 doped with Ru is formed between the p-type InP substrate 10 and the p-type InP clad layer 16. It is known that mutual diffusion does not occur between Ru and Zn. Therefore, the InP diffusion blocking layer 14 prevents Zn diffusion from the p-type InP substrate 10 or the p-type InP buffer layer 12 into the active layer 20. As a result, the device characteristics and the yield can be improved.

Also, the p-type InP clad layer 16 is doped with p-type impurity such as Be or Mg, whose diffusion coefficient is lower than that of Zn. Thereby, the amount of the p-type impurity in the active layer 20 can be reduced. Then, a sharp doping profile can be realized near the active layer 20, and thereby the characteristics of the semiconductor optical element can be improved. The p-type impurity such as Be or Mg can not be doped into all p-type layers but only p-type clad layer.

The Zn concentration of the p-type InP substrate 10 is high (2 to 4×10¹⁸ cm⁻³) and a lot of passive Zn atoms are arranged in the interstitial site of the p-type InP substrate 10. The Zn atoms arranged in the interstitial site easily diffuse. The p-type InP buffer layer 12, whose Zn concentration is lower than that of the p-type InP substrate 10, is formed between the p-type InP substrate 10 and the InP diffusion blocking layer 14. This allows Zn diffusion from the p-type InP substrate 10 to be suppressed.

Also, the thicknesses of the p-type InP buffer layer 12 and the InP diffusion blocking layer 14 are setted respectively so that Zn is not diffused from the p-type InP substrate 10 into the active layer 20 by the heat treatment in the subsequent crystal growth or process. However, the InP diffusion blocking layer 14 doped with Ru is semi-insulating as a Fe-doped InP. Therefore, the resistance of the semiconductor optical element is increased by forming the InP diffusion blocking layer 14. Therefore, the InP diffusion blocking layer 14 has a thickness so as to prevent Zn diffusion, but the thickness is set to be as thin as possible.

If the semi-insulating InP diffusion blocking layer 14 exists above the bottoms of the mesa stripe 28 and the isolation groove 38, the current path is constricted and the device resistance is significantly increased. Thereby, the device characteristics is deteriorated. Therefore, the InP diffusion blocking layer 14 is formed under the bottoms of the mesa stripe 28 and the isolation groove 38.

In this embodiment, the InGaAsP semiconductor laser was described. However, the present invention is effective in a semiconductor laser including an active layer made of a material which can be heteroepitaxially-grown on an InP substrate. Furthermore, the identical effect can be expected not only in a semiconductor laser but also in other semiconductor optical elements such as an optical modulator, a photodiode, or a semiconductor optical element wherein a semiconductor laser, a optical modulator and a photodiode are integrated.

In this embodiment, the mesa stripe 28 and the isolation groove 38 are formed by wet etching. However, the present invention is not limited thereto, but they can be formed by dry etching such as RIE (Reactive Ion Eching). In this embodiment, the crystal growth is performed by MOCVD. However, the present invention is not limited thereto, but molecular beam epitaxy (MBE) or liquid phase epitaxy (LPE) can be used.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2009-141782, filed on Jun. 15, 2009 including specification, claims, drawings and summary, on which the Convention priority of the present application is based, are incorporated herein by reference in its entirety.

1. A semiconductor optical element comprising:
a p-type InP substrate doped with Zn; and
a diffusion blocking layer doped with Ru, a p-type InP cladding layer, an active layer, and an n-type InP cladding layer which are sequentially arranged on the p-type InP substrate.

2. The semiconductor optical element according to claim 1, wherein the p-type InP cladding layer is doped with an impurity producing p-type conductivity and having a diffusion coefficient lower than Zn in InP.

3. The semiconductor optical element according to claim 1, further comprising a p-type InP buffer layer located between the p-type InP substrate and the diffusion blocking layer, wherein
the p-type InP buffer layer is doped with Zn, and
Zn concentration in the p-type InP buffer layer is lower than in the p-type InP substrate.

4. The semiconductor optical element according to claim 1, wherein the p-type InP cladding layer, the active layer, and the n-type InP cladding layer are included in a mesa stripe, and the diffusion blocking layer is located opposite a bottom of the mesa stripe.

5. The semiconductor optical element according to claim 4, further comprising:
a burying layer and a current blocking layer which are located on both sides of the mesa stripe; and
an n-type contact layer on the n-type InP cladding layer, wherein
the n-type InP contact layer, the burying layer, and the current blocking layer define an isolation groove, and
the diffusion blocking layer is located opposite a bottom of the isolation groove.
